(19) United States
(12) Patent Application Publication
(10) Pub. No.: US 2021/0170907 A1
(43) Pub. Date: Jun. 10, 2021

(54) VEHICLE AND METHOD OF CONTROLLING THE SAME

(71) Applicants: HYUNDAI MOTOR COMPANY, SEOUL (KR); KIA MOTORS CORPORATION, SEOUL (KR)

(72) Inventors: Heegun Yang, Anyang-si (KR); SangJae Han, Hwaseong-si (KR); Jin Kim, Suwon-si (KR); Hyunwook Kim, Seoul (KR)

(21) Appl. No.: 17/004,341

(22) Filed: Aug. 27, 2020

(30) Foreign Application Priority Data
Dec. 6, 2019 (KR) 10-2019-0161639

(51) Int. Cl. B60L 58/16; H02J 7/00; G01R 31/371; G01R 31/382; G01R 31/392; B60L 58/12

(52) U.S. Cl. CPC B60L 58/16; H02J 7/005; H02J 7/0048; B60L 58/12; G01R 31/382; G01R 31/392; G01R 31/371

(57) ABSTRACT

Provided is a vehicle including a battery, a display configured to display a capacity of the battery, a sensor module configured to detect the capacity of the battery, and a controller configured to determine at least one of a discharging efficiency, an occurrence of deep discharge, and a charging efficiency of the battery on the basis of a result of the detection of the sensor module and a preset reference, and control the display to display at least one of a replacement notification and a charge notification of the battery on the basis of a result of the determination.

### CROSS REFERENCE TO RELATED APPLICATIONS

This application is based on and claims priority under 35 U.S.C. § 119 to Korean Patent Application No. 10-2019-0161639, filed on Dec. 6, 2019 in the Korean Intellectual Property Office, the disclosure of which is incorporated herein by reference.

### BACKGROUND

### 1. Field

The disclosure relates to a vehicle and a method of controlling the same, and more specifically, to a technology for notifying a user of replacement or charging for a battery provided in a vehicle.

### 2. Description of the Related Art

In general, a battery is provided in a vehicle and has a characteristic of being discharged over time.

Therefore, before a new vehicle is delivered to a customer, the battery quality of the vehicle needs to be determined. However, there is no technology capable of determining degradation of the battery because the vehicle is left in stock for a long time.

### SUMMARY

Therefore, it is an object of the disclosure to provide a vehicle capable of diagnosing at least one of a battery charge efficiency, a deep discharge efficiency, or a discharging efficiency using a battery sensor and perform learning, and a method of controlling the same.

It is another object of the disclosure to provide a vehicle capable of providing a user with a battery charge notification or a battery replacement notification on the basis of a diagnosed battery quality.

Additional aspects of the disclosure will be set forth in part in the description which follows and, in part, will be obvious from the description, or may be learned by practice of the disclosure.

Therefore, it is an aspect of the disclosure to provide a vehicle including a battery, a display configured to display a capacity of the battery, a sensor module configured to detect the capacity of the battery, and a controller configured to determine at least one of a discharging efficiency, an occurrence of deep discharge, and a charging efficiency of the battery on the basis of a result of the detection of the sensor module and a preset reference, and control the display to display at least one of a replacement notification and a charge notification of the battery on the basis of a result of the determination.

The controller may determine whether the vehicle has been operated for a preset period of time, and in consideration of a result of the determination, determine the at least one of the discharging efficiency, the occurrence of deep discharge, and the charging efficiency of the battery on the basis of the result of the detection of the sensor module and the preset reference.

The controller may compare an initial capacity of the battery with a capacity of the battery after the vehicle is driven and determines the charging efficiency on the basis of a result of the comparison.

The controller may determine a chargeable range of the battery.

The controller may generate a preset magnitude of current in the battery, determine capacity reduction of the battery according to the current, and determine the discharging efficiency of the battery on the basis of a result of the determination of the capacity reduction.

The vehicle may further include a storage in which big data regarding a battery capacity is stored, wherein the controller may determine the at least one of the discharging efficiency, the occurrence of deep discharge, and the charging efficiency of the battery according to the big data.

The controller may learn capacity change of the battery on the basis of a result of the detection of the sensor module.

The controller may determine a travel distance of the vehicle, and determine a reduction rate of the capacity of the battery on the basis of a result of the determination of the travel distance.

The controller may determine a non-operation time of the vehicle, and determine a reduction rate of the capacity of the battery on the basis of a result of the determination of the non-operation time of the vehicle.

The controller may determine whether the battery has been replaced, and determine the at least one of the discharging efficiency, the occurrence of deep discharge, and the charging efficiency of the battery on the basis of the result of the determination of the replacement of the battery.

It is another aspect of the disclosure to provide a method of controlling a vehicle, the method including displaying a capacity of a battery, detecting a capacity of the battery, and determining at least one of a discharging efficiency, an occurrence of deep discharge, and a charging efficiency of the battery on the basis of a result of the detection and a preset reference, and controlling a display to display at least one of a replacement notification and a charge notification of the battery on the basis of a result of the determination.

The controlling may include determining whether the vehicle has been operated for a preset period of time, in consideration of a result of the determination, determining the at least one of the discharging efficiency, the occurrence of deep discharge, and the charging efficiency of the battery on the basis of the result of the detection and the preset reference, and controlling the display to display the at least one of the replacement notification and the charging notification of the battery on the basis of the result of the determination.

The controlling may include comparing an initial capacity of the battery with a capacity of the battery after the vehicle is driven and determining the charging efficiency on the basis of a result of the comparison.

The controlling may include determining a chargeable range of the battery.

The controlling may include generating a preset magnitude of current in the battery, determining capacity reduction of the battery according to the current, and determining the discharging efficiency of the battery on the basis of a result of the determination of the capacity reduction.

The method may further include storing big data regarding a battery capacity, wherein the controlling may include determining the at least one of the discharging efficiency, the occurrence of deep discharge, and the charging efficiency of the battery according to the big data.

The controlling may include learning capacity change of the battery on the basis of a result of the detection.

The controlling may include determining a travel distance of the vehicle, and determining a reduction rate of the capacity of the battery on the basis of a result of the determination of the travel distance.

The controlling may include determining a non-operation time of the vehicle, and determining a reduction rate of the capacity of the battery on the basis of a result of the determination of the non-operation time of the vehicle.

The controlling may include determining whether the battery has been replaced, and determining the at least one of the discharging efficiency, the occurrence of deep discharge, and the charging efficiency of the battery on the basis of the result of the determination of the replacement of the battery.

### BRIEF DESCRIPTION OF THE FIGURES

These and/or other aspects of the disclosure will become apparent and more readily appreciated from the following description of the embodiments, taken in conjunction with the accompanying drawings of which:

FIG. 1 is a view illustrating the interior of a vehicle according to an embodiment of the disclosure;

FIG. 2 is a control block diagram illustrating a vehicle according to an embodiment of the disclosure;

FIG. 3 is a flowchart showing a process of controlling a display to display a battery charge notification or a battery replacement notification by a controller according to an embodiment of the disclosure;

FIG. 4 is a view showing a process of displaying a battery replacement notification by a controller according to an embodiment of the disclosure;

FIGS. 5A and 5B are views illustrating the discharging efficiency of a battery having a lowed performance according to an embodiment of the disclosure; and

FIG. 6 is a flowchart showing a process of determining the charging efficiency of a battery by a controller according to an embodiment of the disclosure.

### DETAILED DESCRIPTION

Like numerals refer to like elements throughout the specification. Not all elements of embodiments of the present disclosure will be described, and description of what are commonly known in the art or what overlap each other in the embodiments will be omitted. The terms as used throughout the specification, such as “˜ part”, “˜ module”, “˜ member”, “˜ block”, etc., may be implemented in software and/or hardware, and a plurality of “˜ parts”, “˜ modules”, “˜ members”, or “˜ blocks” may be implemented in a single element, or a single “˜ part”, “˜ module”, “˜ member”, or “˜ block” may include a plurality of elements.

It will be further understood that the term “connect” or its derivatives refer both to direct and indirect connection, and the indirect connection includes a connection over a wireless communication network.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof, unless the context clearly indicates otherwise.

Although the terms “first,” “second,” “A,” “B,” etc. may be used to describe various components, the terms do not limit the corresponding components, but are used only for the purpose of distinguishing one component from another component.

As used herein, the singular forms “a,” “an” and “the” are intended to include the plural forms as well, unless the context clearly indicates otherwise.

Reference numerals used for method steps are just used for convenience of explanation, but not to limit an order of the steps. Thus, unless the context clearly dictates otherwise, the written order may be practiced otherwise.

Hereinafter, the operating principles and embodiments of the present disclosure will be described with reference to the accompanying drawings.

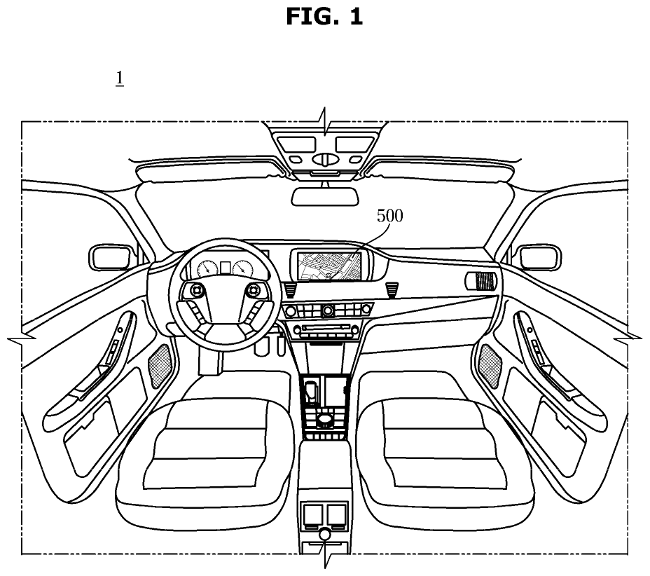

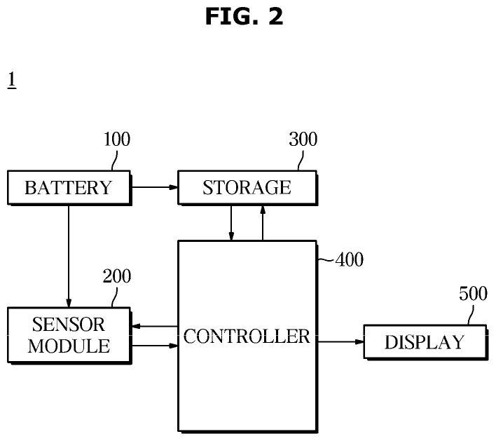

FIGS. 1 and 2 illustrate a vehicle 1 according to an embodiment of the disclosure.

Referring to FIGS. 1 and 2, the vehicle 1 according to the embodiment of the disclosure may include a battery 100, a sensor module 200, a storage 300, a controller 400, and a display 500.

The battery 100 according to the embodiment supplies power to the vehicle 1.

The battery 100 includes a secondary battery capable of repeating charging and discharging. For example, the battery 100 may employ a lithium ion battery. Lithium ion batteries are charged and discharged through a process of lithium ions being doped/undoped while moving between a cathode and an anode. During charging, lithium ions are undoped from the cathode composed of a lithium-containing compound, and are doped between carbon layers of the anode. During discharging, lithium ions are undoped from a carbon layer of the anode and are doped between layers of the cathode compound.

In addition, as for the battery, a plurality of battery cells may be combined with one frame to form a battery module, and a plurality of the battery modules may form one battery 100. That is, the battery 100 including a plurality of battery modules may be referred to as a battery pack.

However, the implementation of the battery 100 is not limited thereto, and the battery 100 may include other devices capable of supplying power to the vehicle 1.

The sensor module 200 according to the disclosed embodiment detects the capacity of the battery 100.

The sensor module 200 may include a battery sensor. The battery sensor may acquire state information related to the battery 100. For example, the battery sensor may measure and output state information of the battery 100, such as a rated capacity of the battery 100, a state of charge (SoC) of the battery 100, a state of health (SoH) of the battery 100, an output voltage of the battery 100, an output current of the battery 100, a temperature of the battery 100, a charging efficiency of the battery 100, a deep discharge efficiency of the battery 100, and a discharging efficiency of the battery 100.

The storage 300 according to the embodiment may store information related to a battery capacity and generate big data of the information related to the battery capacity.

Specifically, the information related to the battery capacity may include discharging efficiency information of the battery 100, deep discharge information of the battery, or charging efficiency information of the battery 100.

The discharging efficiency information of the battery 100 may include a change in discharging efficiency according to age of the battery, under the condition of the same current consumption. In addition, the discharging efficiency information of the battery 100 may include a change in discharging efficiency due to a dark current before the vehicle 1 is delivered to a customer. However, the discharging efficiency information of the battery 100 is not limited thereto and may include other types of information affecting the discharge of the battery 100.

The deep discharge information of the battery 100 may include recovery information of a SoC of the battery 100. In general, when batteries have a low initial SoC, the batteries may also have a low recovery rate of SoC even after the batteries are delivered to the customer and used. However, the deep discharge information of the battery 100 is not limited thereto, and may include other types of information affecting SoC of the battery 100.

The charging efficiency information of the battery 100 may include a difference between an actual capacity of the battery 100 and a charged capacity of the battery 100 according to age of the battery 100. Herein, the charged capacity of the battery 100 refers to power supplied to the battery 100 during charging detected by the battery sensor. However, the charging efficiency information of the battery 100 is not limited thereto and may include other types of information affecting the charging efficiency of the battery 100.

The storage 300 may include a nonvolatile memory device, such as a cache, a read only memory (ROM), a programmable ROM (PROM), an erasable programmable ROM (EPROM), an electrically erasable programmable ROM (EEPROM), and a flash memory, a volatile memory device, such as a random access memory (RAM), or other storage media, such as a hard disk drive (HDD), a CD-ROM, and the like., but the implementation of the storage is not limited thereto. The storage 300 may be a memory implemented as a chip separated from the processor, which will be described below in connection with the controller 400, or may be implemented as a single chip integrated with the processor.

The controller 400 determines at least one of the discharging efficiency, the occurrence of deep discharge, or the charging efficiency, of the battery 100 on the basis of a result of the detection of the sensor module 200 and a preset criterion, and controls the display 500 to display at least one of a replacement notification or a charge notification of the battery 100 on the basis of a result of the determination.

In detail, the controller 400 may determine a change of state (discharging efficiency, deep discharge, charging efficiency) of the battery, and determine whether the state is lowered by 40% or more compared to the initial performance on the basis of a result of the determination.

In addition, according to the embodiment, the controller 400 may determine whether the SoC of the battery 100 has been lowered to a level of 60% or lower compared to that before delivery to the customer.

In addition, the controller 400 generates a current having a preset magnitude in the battery 100, determines decrease in the capacity of the battery 100 according to the generated current, and determines the discharging efficiency of the battery 100 on the basis of a result of the determination.

Here, with regard to the charging efficiency of the battery 100, the controller 400 may determine whether a difference between the charged power and the actual capacity of the battery 100 is greater than or equal to 20%, and determine a chargeable range of the battery 100. In addition, the controller 400 may determine the travel distance of the vehicle 1, and may determine the reduction rate of the capacity of the battery 100 on the basis of a result of the determination.

However, the change of state (discharging efficiency, deep discharge, and charge efficiency) of the battery determined by the controller 400 is not limited thereto and may be differently determined according to a criterion preset by the user.

In addition, the controller 400 may determine whether the vehicle has been operated for a preset time. Here, the preset time refers to a time for which the vehicle 1 is stored in stock. Thus, the preset time may vary depending on a general shipping time or customer delivery time of the vehicle 1. In addition, the controller 400 may determine a non-operation time of the vehicle 1 after delivery of the vehicle 1.

In addition, the controller 400 may determine whether the battery 100 has been replaced, and determine at least one of the discharging efficiency, the deep discharge, and the charging efficiency of the battery 100 on the basis of a result of the determination of replacement.

The controller 400 may include a memory (not shown) for storing data regarding an algorithm for controlling the operations of the components of the vehicle 1 or a program that represents the algorithm, and a processor (not shown) that performs the above described operations using the data stored in the memory. In this case, the memory and the processor may be implemented as separate chips. Alternatively, the memory and the processor may be implemented as a single chip.

The display 500 according to the embodiment may display the capacity of the battery 100 and display at least one of a charge notification and a replacement notification of the battery 100.

In detail, the display 500 may include a cathode ray tube (CRT), a digital light processing (DLP) panel, a plasma display panel, a liquid crystal display (LCD) panel, an electro luminescence (EL) panel, an electrophoretic display (EPD) panel, an electrochromic display (ECD) panel, a light emitting diode (LED) panel or an organic light emitting diode (OLED), but is not limited thereto.

In addition, when the display 500 is provided as a touch screen panel (TSP) having a layer structure with a touch pad, the display 500 may be used as an input device for receiving a user's command.

The input device may include a hardware device, such as various types of buttons or switches, pedals, keyboards, mouse, track-balls, various levers, handles, or sticks.

In addition, the input device may include a graphical user interface (GUI), such as a touch pad, for a user input, that is, a software device. The touch pad may be implemented as a touch screen panel (TSP) to form a mutual layer structure together with the display.

At least one component may be added or omitted to correspond to the performances of the components of the vehicle 1 shown in FIG. 2. In addition, the mutual positions of the components may be changed to correspond to the performance or structure of the system.

Some of the components shown in FIGS. 1 and 2 may refer to a software component and/or a hardware component, such as a Field Programmable Gate Array (FPGA) and an Application Specific Integrated Circuit (ASIC).

Hereinafter, a process of controlling the vehicle 1 by the controller 400 will be described in detail.

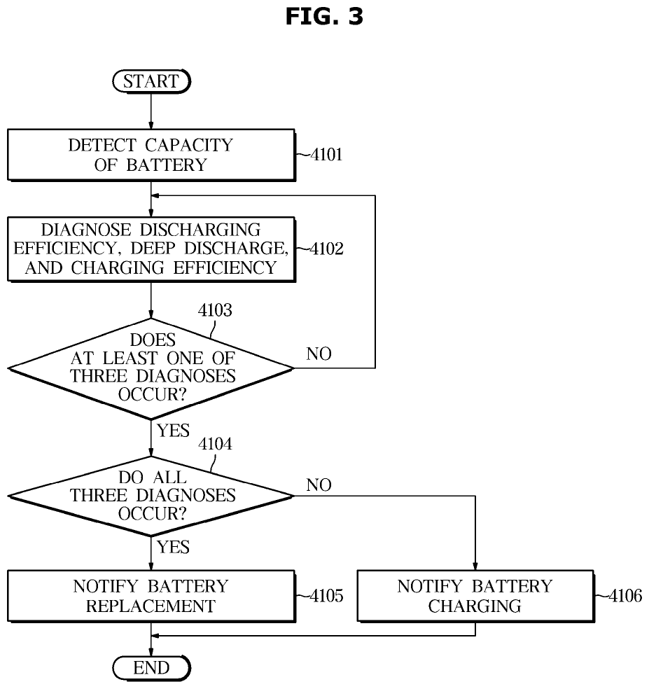

FIG. 3 is a flowchart showing a process of controlling a display to display a battery charge notification or a battery replacement notification by a controller, according to an exemplary embodiment.

Referring to FIG. 3, the sensor module 200 detects the capacity of the battery 100 at 4101.

The controller 400 diagnoses at least one of the discharging efficiency, the occurrence of deep discharge, and the charging efficiency of the battery 100 on the basis of the detected capacity of the battery 100 at 4102. The controller 400 may diagnose at least one of the discharging efficiency, the occurrence of deep discharge, and the charging efficiency of the battery 100 on the basis of a detection result detected by the battery sensor.

The controller 400 may determine whether a diagnosis on at least one of the discharging efficiency, the occurrence of deep discharge, and the charging efficiency of the battery 100 is required at 4103.

When it is determined that a diagnosis on at least one of the discharging efficiency, the occurrence of deep discharge, and the charging efficiency of the battery 100 is required, the controller 400 may determine whether diagnoses on all of the discharging efficiency, the occurrence of deep discharge, and the charging efficiency of the battery 100 have occurred at 4104.

However, when it is determined that no diagnosis on the discharging efficiency, the occurrence of deep discharge, and the charging efficiency of the battery 100 is required, the controller 400 continuously determines whether a diagnosis on at least one of the discharging efficiency, the occurrence of deep discharge, and the charging efficiency of the battery 100 is required.

If it is determined that diagnoses on all of the discharging efficiency, the occurrence of deep discharge, and the charging efficiency of the battery 100 are required or have occurred, the controller 400 controls the display 500 to display a replacement notification of the battery 100 at 4105.

However, if it is determined that diagnoses on all of the discharging efficiency, the occurrence of deep discharge, and the charging efficiency of the battery 100 have not occurred or are not required, and diagnosis on only one or two of the discharging efficiency, the occurrence of deep discharge, and the charging efficiency of the battery 100 have occurred or are required, the controller 400 controls the display 500 to display a charge notification of the battery 100 at 4106.

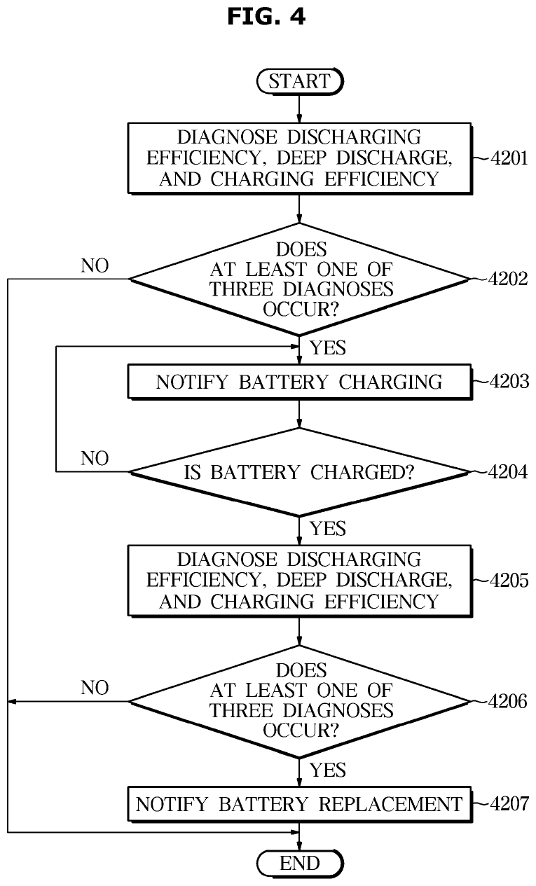

FIG. 4 illustrates a process of displaying a replacement notification of the battery 100 according to an embodiment.

Referring to FIG. 4, the controller 400 diagnoses at least one of the discharging efficiency, the occurrence of deep discharge, and the charging efficiency of the battery 100 at 4201.

As described above, if it is determined that a diagnosis on at least one of the discharging efficiency, the occurrence of deep discharge, and the charge efficiency of the battery 100 has occurred, the controller 400 controls the display 500 to display a charge notification of the battery 100 at 4202 and 4203. However, if it is determined that no diagnosis on the discharging efficiency, the occurrence of deep discharge, and the charge efficiency diagnosis on the battery 100 has occurred, the controller 400 ends the control process of the vehicle 1.

If the charge notification of the battery 100 is displayed, the controller 400 determines whether the battery 100 has been charged at 4204.

If it is determined that the battery 100 has been charged, the controller 400 diagnoses at least one of the discharging efficiency, the occurrence of deep discharge, and the charging efficiency of the battery 100 at 4205. However, if it is determined that the battery 100 has not been charged, the controller 400 controls the display 500 to continuously display the charge notification of the battery 100.

If it is determined that a diagnosis on at least one of the discharging efficiency, the occurrence deep discharge, or the charge efficiency of the charged battery 100 has occurred, the controller 400 no longer displays a charge notification of the battery 100, and controls the display 500 to display a replacement notification of the battery 100 instead of the charge notification at 4206 and 4207. However, if it is determined that no diagnosis on the discharging efficiency, the occurrence of deep discharge, and the charge efficiency of the charged battery 100 has occurred, the controller 400 no longer generates a notification signal related to replacing or charging the battery 100 and ends the control process of the vehicle.

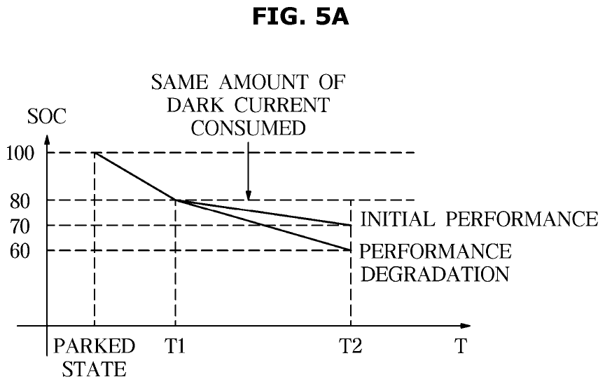

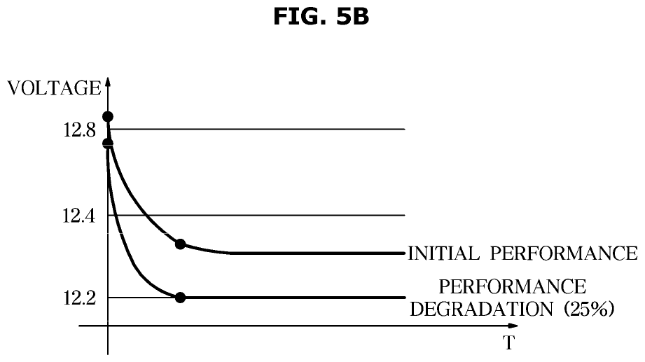

FIGS. 5A and 5B are views illustrating the discharging efficiency of a battery having a lowered performance according to one embodiment of the disclosure.

FIG. 5A illustrates a SoC of the battery 100 according to a discharge time of the battery 100.

Referring to FIG. 5A, the x-axis denotes a discharge time T of the battery 100, and the y-axis denotes a SoC of the battery 100.

It can be seen that when the same amount of dark current is generated, a normal battery according to the disclosed embodiment has a SoC of 70% of that in a parked state, whereas an aged battery has a SoC of 60% of that in a parking state. However, the value of SoC of the battery 100 according to the discharge time of the battery 100 is not limited to the above as a reference value, and may vary depending on the performance, type, or age of the battery 100.

FIG. 5B illustrates the voltage of the battery 100 according to the discharge time of the battery 100.

Referring to FIG. 5B, the x-axis denotes a discharge time T of the battery 100, and the y-axis denotes a voltage of the battery 100.

It can be seen that when the same amount of dark current is generated, an aged battery according to the disclosed embodiment has a voltage drop of 25% compared to the initial voltage. However, the value of the voltage of the battery 100 according to the discharge time of the battery 100 is not limited to the above as a reference, and may vary according to the performance, type, or age of the battery 100.

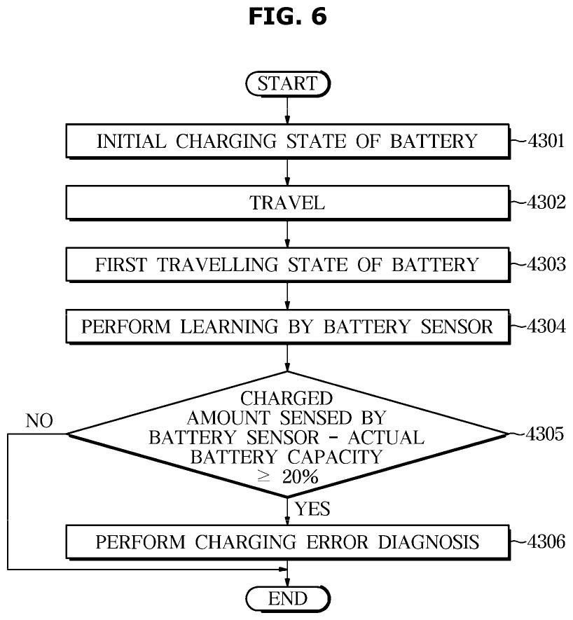

FIG. 6 is a flowchart showing a process of determining a charging efficiency of the battery 100 by the controller 400 according to the embodiment of the disclosure.

The controller 400 according to the disclosed embodiment determines initial charging state information of the battery 100 at 4301.

The controller 400 determines whether the vehicle 1 has traveled at 4302.

If it is determined that the vehicle 1 has traveled, the controller 400 determines the capacity of the battery 100 after the travel as a first travelling state at 4303. As the vehicle repeatedly performs travel, the controller 400 determines the travel-executed capacity of the battery 100 as a n^{th} travelling state, such as the second travelling state, the third travelling state, and the like, and learns the determined capacity of the battery 100 or a change of capacity of the battery 100 at 4304.

In addition, the controller 400 may compare the supplied power sensed by the battery sensor with the actually charged capacity of the battery 100, and determine the charging efficiency of the battery 100 on the basis of a result of the comparison.

The controller 400 determines whether the difference between the charge amount of the battery 100 sensed by the battery sensor and the actually charged battery capacity is 20% or more at 4305.

If it is determined that the difference between the charge amount of the battery 100 sensed by the battery sensor and the actually charged battery charge is 20% or more, the controller 400 determines that there is an error in the charging efficiency of the battery 100, and performs a charging error diagnosis on the battery 100 at 4306. However, if it is determined that the difference between the charge amount of the battery 100 sensed by the battery sensor and the actually charged battery capacity is less than 20%, the controller 400 ends the process of diagnosing the charging efficiency of the battery 100.

However, the difference between the charge amount of the battery 100 sensed by the battery sensor and the actually charged capacity of the battery is not limited to 20%, and the charging efficiency of the battery 100 may be determined on the basis of a different value according to a user definition.

Meanwhile, the disclosed embodiments may be embodied in the form of a recording medium storing instructions executable by a computer. The instructions may be stored in the form of program code and, when executed by a processor, may generate a program module to perform the operations of the disclosed embodiments. The recording medium may be embodied as a computer-readable recording medium.

The computer-readable recording medium includes all kinds of recording media in which instructions which can be decoded by a computer are stored, for example, a Read Only Memory (ROM), a Random Access Memory (RAM), a magnetic tape, a magnetic disk, a flash memory, an optical data storage device, and the like.

As is apparent from the above, the vehicle and the method of controlling the same can notify a user whether the battery quality is low before customer delivery of the vehicle, and preventing battery quality related errors from occurring.

In addition, the vehicle and the method of controlling the same can provide a user with a battery charge notification or a battery replacement notification on the basis of a diagnosed battery quality.

Although exemplary embodiments of the present disclosure have been described for illustrative purposes, those skilled in the art will appreciate that various modifications, additions and substitutions are possible, without departing from the scope and spirit of the disclosure. Therefore, exemplary embodiments of the present disclosure have not been described for limiting purposes

1. A vehicle comprising:
a battery;
a display configured to display a capacity of the battery;
a sensor module configured to detect the capacity of the battery; and
a controller configured to determine at least one of a discharging efficiency, an occurrence of deep discharge, and a charging efficiency of the battery on the basis of a result of the detection of the sensor module and a preset reference, and control the display to display at least one of a replacement notification and a charge notification of the battery on the basis of a result of the determination.

2. The vehicle of claim 1, wherein the controller determines whether the vehicle has been operated for a preset period of time, and in consideration of a result of the determination, determines the at least one of the discharging efficiency, the occurrence of deep discharge, and the charging efficiency of the battery on the basis of the result of the detection of the sensor module and the preset reference.

3. The vehicle of claim 1, wherein the controller compares an initial capacity of the battery with a capacity of the battery after the vehicle is driven and determines the charging efficiency on the basis of a result of the comparison.

4. The vehicle of claim 3, wherein the controller determines a chargeable range of the battery.

5. The vehicle of claim 1, wherein the controller generates a preset magnitude of current in the battery, determines capacity reduction of the battery according to the current, and determines the discharging efficiency of the battery on the basis of a result of the determination of the capacity reduction.

6. The vehicle of claim 1, further comprising a storage in which big data regarding a battery capacity is stored,
wherein the controller determines the at least one of the discharging efficiency, the occurrence of deep discharge, and the charging efficiency of the battery according to the big data.

7. The vehicle of claim 1, wherein the controller learns capacity change of the battery on the basis of a result of the detection of the sensor module.

8. The vehicle of claim 1, wherein the controller determines a travel distance of the vehicle, and determines a reduction rate of the capacity of the battery on the basis of a result of the determination of the travel distance.

9. The vehicle of claim 1, wherein the controller determines a non-operation time of the vehicle, and determines a reduction rate of the capacity of the battery on the basis of a result of the determination of the non-operation time of the vehicle.

10. The vehicle of claim 1, wherein the controller determines whether the battery has been replaced, and determines the at least one of the discharging efficiency, the occurrence of deep discharge, and the charging efficiency of the battery on the basis of the result of the determination of the replacement of the battery.

11. A method of controlling a vehicle, the method comprising:
displaying a capacity of a battery;
detecting a capacity of the battery; and
determining at least one of a discharging efficiency, an occurrence of deep discharge, and a charging efficiency of the battery on the basis of a result of the detection and a preset reference, and controlling a display to display at least one of a replacement notification and a charge notification of the battery on the basis of a result of the determination.

12. The method of claim 11, wherein the controlling includes:
determining whether the vehicle has been operated for a preset period of time;
in consideration of a result of the determination, determining the at least one of the discharging efficiency, the occurrence of deep discharge, and the charging efficiency of the battery on the basis of the result of the detection and the preset reference; and
controlling the display to display the at least one of the replacement notification and the charging notification of the battery on the basis of the result of the determination.

13. The method of claim 11, wherein the controlling includes:
comparing an initial capacity of the battery with a capacity of the battery after the vehicle is driven and determining the charging efficiency on the basis of a result of the comparison.

14. The method of claim 13, wherein the controlling includes determining a chargeable range of the battery.

15. The method of claim 11, wherein the controlling includes:
generating a preset magnitude of current in the battery;
determining capacity reduction of the battery according to the current; and
determining the discharging efficiency of the battery on the basis of a result of the determination of the capacity reduction.

16. The method of claim 11, further comprising storing big data regarding a battery capacity,
wherein the controlling includes determining the at least one of the discharging efficiency, the occurrence of deep discharge, and the charging efficiency of the battery according to the big data.

17. The method of claim 11, wherein the controlling includes learning capacity change of the battery on the basis of a result of the detection.

18. The method of claim 11, wherein the controlling includes determining a travel distance of the vehicle, and determining a reduction rate of the capacity of the battery on the basis of a result of the determination of the travel distance.

19. The method of claim 11, wherein the controlling includes determining a non-operation time of the vehicle, and determining a reduction rate of the capacity of the battery on the basis of a result of the determination of the non-operation time of the vehicle.

20. The method of claim 11, wherein the controlling includes determining whether the battery has been replaced, and determining the at least one of the discharging efficiency, the occurrence of deep discharge, and the charging efficiency of the battery on the basis of the result of the determination of the replacement of the battery.
